(19) United States
(12) Patent Application Publication
(10) Pub. No.: US 2026/0334118 A1
(43) Pub. Date: Oct. 22, 2026

(54) METHOD OF PROCESSING SUBSTRATE

(71) Applicant: TES Co., Ltd, Yongin-si (KR)

(72) Inventors: YoungHwi KWON, Yongin-si (KR); Donggeun CHOI, Yongin-si (KR); Sangjoon PARK, Yongin-si (KR)

(73) Assignee: TES Co., Ltd, Yongin-si (KR)

(21) Appl. No.: 19/633,300

(22) Filed: Mar. 30, 2026

(30) Foreign Application Priority Data
Apr. 16, 2025 (KR) 10-2025-0049799

(51) Int. Cl. H10P 50/24; H10P 14/60

(52) U.S. Cl. CPC H10P 50/242; H10P 14/6532

(57) ABSTRACT

A method of processing a substrate, which selectively etches SiGe layers laterally in a Si—SiGe stack in which Si layers and the SiGe layers are alternately stacked on the substrate, includes modifying surfaces of the Si layers to form silicon nitride thereon by generating plasma from a nitrogen-containing pretreatment gas, and etching the SiGe layers using an etching gas.

### CROSS REFERENCE TO RELATED APPLICATION

The present application claims priority to Korean Patent Application No. 10-2025-0049799 (filed on Apr. 16, 2025), which is hereby incorporated by reference in its entirety.

### BACKGROUND

The present disclosure relates to a method of processing a substrate, which selectively etches SiGe layers in an Si—SiGe stack in which Si layers and the SiGe layers are alternately stacked on a substrate. More specifically, the present disclosure relates to a method of processing a substrate, which can improve SiGe etch selectivity and SiGe etch uniformity.

Research is actively underway on a three-dimensional (3D) DRAM, which is one of a next-generation dynamic random access memory (DRAM). Like the 3D NAND, since the 3D DRAM stacks memories vertically, it can theoretically increase device density indefinitely. To use silicon as a transistor in the 3D DRAM, there is a need for a process of selectively etching the SiGe layers after alternately depositing tens to hundreds of silicon (Si) and silicon germanium (SiGe) layers.

A method using a fluorine-containing gas, such as ClF₃, as an etchant is used to selectively laterally etch the SiGe layers in an Si—SiGe stack in which Si and SiGe layers are alternately stacked.

To increase the etch selectivity of the SiGe layers in the Si—SiGe stack, it is necessary to minimize the etching of the Si layers during the etching of the SiGe layers.

### SUMMARY

The present disclosure is directed to providing a method of processing a substrate, which can improve SiGe etch selectivity and SiGe etch uniformity when performing selective lateral etching of an SiGe layer in a stack in which several to several hundred layers of Si layers and SiGe layers are alternately stacked.

According to an embodiment of the present disclosure, there is provided a method of processing a substrate, which selectively etches SiGe layers laterally in a Si—SiGe stack in which Si layers and the SiGe layers are alternately stacked over the substrate, which includes (a) modifying surfaces of the Si layers to form silicon nitride thereon by generating plasma from a nitrogen-containing pretreatment gas, and (b) etching the SiGe layers using an etching gas.

In the step (a), the pretreatment gas may include a nitrogen gas.

In the step (a), the plasma generation from the nitrogen-containing pretreatment gas may be performed above a showerhead.

The step (a) may be performed under a process pressure condition of about 0.5 to about 2.0 Torr.

The step (a) may be performed under an RF power condition of about 100 to about 1,500 W.

The step (a) may be performed under an RF power application time condition of about 5 to about 60 seconds.

In the step (b), the etching gas may include a fluorine component. The etching gas may include a fluorine gas. The etching gas may include a fluorine-containing inter-halogen gas.

The method may further include, prior to the step (a), removing a native oxide film of the Si—SiGe stack.

The steps (a) and (b) may be repeated multiple times.

According to an embodiment of the present disclosure, there is provided a method of processing a substrate, which selectively etches SiGe layers laterally in a Si—SiGe stack in which Si layers and the SiGe layers are alternately stacked over the substrate, which includes (a) arranging the substrate in a first reaction chamber and modifying surfaces of the Si layers to form silicon nitride thereon by generating plasma from a nitrogen-containing pretreatment gas, (b) unloading the substrate from the first reaction chamber, and (c) arranging the substrate in a second reaction chamber and etching the SiGe layer using an etching gas.

In the step (a), the pretreatment gas may include a nitrogen gas.

In the step (a), the plasma generation from the nitrogen-containing pretreatment gas may be performed above a showerhead.

The step (a) may be performed under a process pressure condition of about 0.5 to about 2.0 Torr.

The step (a) may be performed under an RF power condition of about 100 to about 1,500 W.

The step (a) may be performed under an RF power application time condition of about 5 to about 60 seconds.

In the step (c), the etching gas may include a fluorine component.

The method may further include, prior to the step (a), removing a native oxide film of the Si—SiGe stack.

The steps (a) to (c) may be repeated multiple times.

### BRIEF DESCRIPTION OF THE DRAWINGS

FIG. 1 schematically illustrates an example of selectively etching SiGe layers in a stack by including a native oxide removing step and an etching step.

FIG. 2 schematically illustrates an example of forming an etching protective film on Si layers while SiGe layers are etched when an etching gas and a nitrogen-containing gas are supplied together during the etching step.

FIG. 3A is a schematic flowchart illustrating a method of processing a substrate according to an embodiment of the present disclosure.

FIG. 3B is a schematic flowchart illustrating a method of processing a substrate according to another embodiment of the present disclosure.

FIG. 4A schematically illustrates an example in which surfaces of Si layers are modified into silicon nitride during nitrogen-containing gas plasma pretreatment.

FIG. 4B schematically illustrates an example in which SiGe layers are etched in a state in which the surfaces of the Si layers are modified into silicon nitride.

FIG. 5A schematically illustrates an example of a first reaction chamber in which the nitrogen-containing gas plasma pretreatment step is performed.

FIG. 5B schematically illustrates an example of a second reaction chamber in which an SiGe etching step is performed.

FIGS. 6A to 6E illustrate SiGe etching results according to the process pressure of the plasma pretreatment step.

FIGS. 7A to 7E illustrate SiGe etching results according to the RF power of the plasma pretreatment step.

FIGS. 8A to 8E illustrate SiGe etching results according to the plasma exposure time of the plasma pretreatment step.

### DETAILED DESCRIPTION

Advantages and features of the present disclosure and methods for achieving them will become clear with reference to various embodiments to be described below in detail together with the accompanying drawings. However, the present disclosure is not limited to the embodiments disclosed below but can be implemented in various different forms, the embodiments are merely provided to make the disclosure of the present disclosure complete and fully inform those skilled in the art to which the present disclosure pertains of the scope of the present disclosure, and the present disclosure is only defined by the scope of the appended claims.

When a component or layer is described as being “above” or “below” the other component or layer, it includes not only a case in which the component or layer is directly on or under the other component or layer, but also includes a case in which another layer or component is interposed therebetween. In addition, when a certain component is described as being “connected,” “coupled,” or “joined” to the other component, the components may be directly connected or joined, but it should be understood that another component may be “interposed” between the components, or the components may be “connected,” “coupled,” or “joined” through another component.

Terms used in the present specification are for describing various embodiments and thus are not intended to limit the present disclosure. In the present specification, the singular form also includes the plural form unless specifically stated in the phrase. As used herein, “includes” and/or “including” means that the stated device, step, and/or operation do not preclude the presence or addition of one or more other components, devices, steps, and/or operations.

Hereinafter, a method of processing a substrate according to exemplary embodiments of the present disclosure will be described in detail with reference to the accompanying drawings as follows.

The present disclosure provides a method of processing a substrate for laterally etching SiGe layers in an Si—SiGe stack in which several to several hundred layers of Si layers and SiGe layers are alternately stacked on the substrate.

Hereinafter, the term “stack” refers to an Si—SiGe stack in which several to several hundred layers of Si layers and SiGe layers are alternately stacked. For example, the Ge content of the SiGe layer may range from 3 to 50%, but is not limited thereto. A hole is formed in a central region of the stack from top to bottom to expose side surfaces of the Si and SiGe layers constituting the stack. In addition, the stack may be patterned into a plurality of stacks. Etching is performed laterally from the side surfaces of the stack. In the present specification, a silicon layer may also be referred to as an Si layer, silicon, or Si, and a silicon germanium layer may also be referred to as an SiGe layer, silicon germanium, or SiGe.

The Si—SiGe stack may be disposed directly on a substrate. In another example, an intermediate layer may be disposed between the Si—SiGe stack and the substrate.

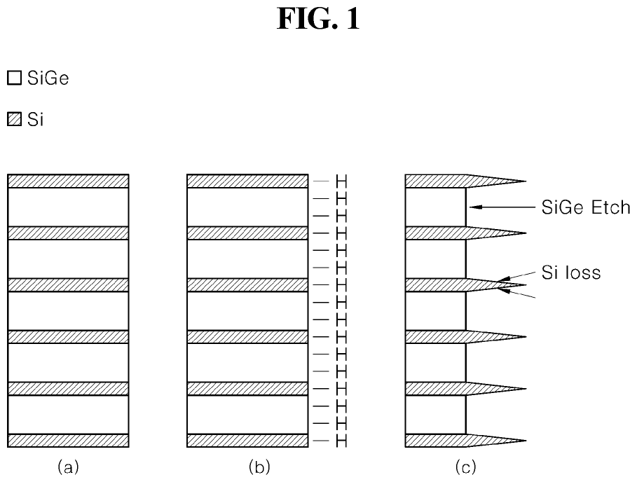

FIG. 1 schematically illustrates an example of selectively etching SiGe in a stack by including a native oxide removing step and an etching step.

When the native oxide removing step is performed on a stack in which Si and SiGe layers are alternately stacked on a substrate, as illustrated in FIG. 1A, using a mixed gas such as HF/NH₃, exposed side surfaces of the Si and SiGe layers of the stack may be modified with hydrogen (—H), as illustrated in FIG. 1B. Subsequently, dry etching using a fluorine-containing compound, such as ClF₃ gas, may selectively etch the SiGe layer, as illustrated in FIG. 1C.

In this case, during the etching step, both the SiGe layers and the Si layers are partially etched, resulting in undesirable loss in the Si layers.

Accordingly, it is necessary to reduce the loss in the Si layers, thereby improving the SiGe etch selectivity.

To increase the etch selectivity of the SiGe layers in the Si—SiGe stack, it is necessary to minimize the etching of the Si layers during the etching of the SiGe layers. To this end, the inventors of the present disclosure have devised a method of forming an etch passivation layer on surfaces of Si layers during etching of SiGe layers.

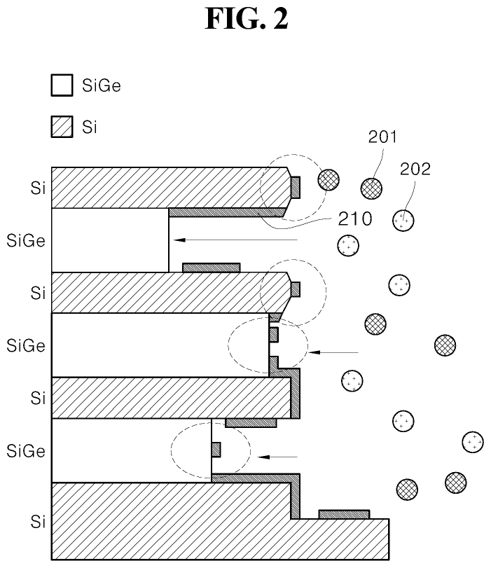

FIG. 2 schematically illustrates an example of non-uniformly forming an etching protective film on Si layers while SiGe layers are etched when an etching gas and a nitrogen-containing gas are supplied together during the etching step.

To increase the etch selectivity of the SiGe layers in an Si—SiGe stack, a nitrogen-containing gas 201 may be supplied into the reaction chamber together with an etching gas 202, which is a fluorine-containing gas. In this case, nitrogen radicals (N radicals) react with Si to form a nitrogen-containing film 210, such as a silicon nitride film, and the silicon nitride film serves as the etch passivation layer.

Meanwhile, the surface reactivity of the SiGe layers increases during the etching process. The high surface reactivity of the SiGe layers increases reaction between nitrogen radicals and SiGe, resulting in the non-uniform formation of the nitrogen-containing film 210, such as SiN or SiGeN, not only on the Si layer but also on the SiGe layer. The nitrogen-containing film 210 formed non-uniformly on the SiGe layers serves as an unwanted etch passivation layer to interfere with SiGe etching, resulting in a reduction in etch uniformity of the SiGe layers.

Accordingly, the present disclosure provides a method of processing a substrate, which can improve SiGe etch selectivity and enhance etch uniformity by reducing the loss of an Si layer.

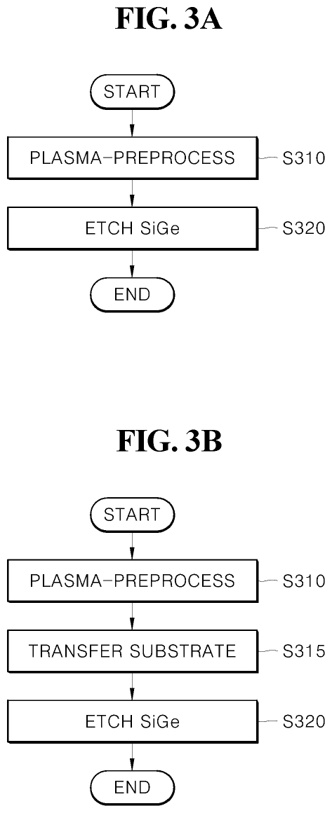

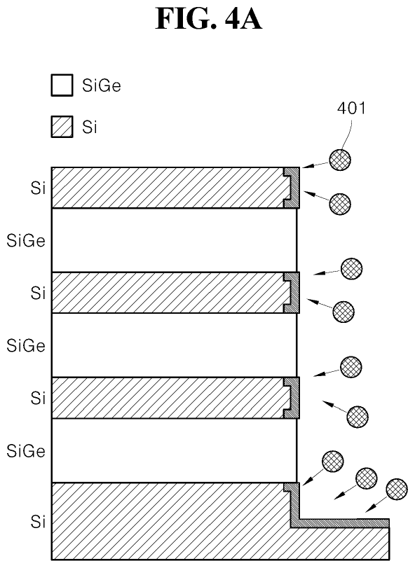

FIG. 3A is a schematic flowchart illustrating a method of processing a substrate according to an embodiment of the present disclosure.

Referring to FIG. 3A, the method of processing a substrate includes a plasma pretreatment step S310 and an SiGe etching step S320. A native oxide removing step may be added prior to the plasma pretreatment step.

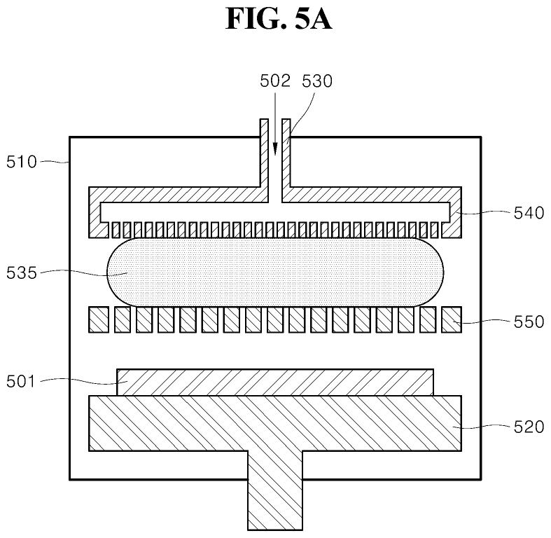

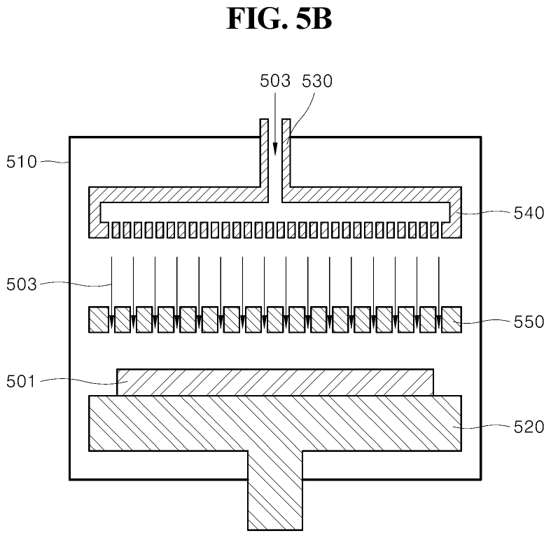

The method of processing a substrate illustrated in FIG. 3 may be performed in situ in a reaction chamber, such as the example illustrated in FIG. 5A. The substrate to be treated, that is, a substrate in which Si and SiGe layers are alternately stacked, is disposed on a susceptor within the reaction chamber. Subsequently, the substrate is heated as needed. Subsequently, stabilization within the reaction chamber may be performed using an inert gas such as argon.

Without wishing to be bound by theory, the inventors have recognized that the activation energy required for nitridation of Ge is higher than that required for nitridation of Si and silicon nitride requires a higher energy for reaction with fluorine than silicon germanium.

When plasma pretreatment for forming an Si—N etching protective film and SiGe etching are performed simultaneously, it is difficult to optimize the individual reaction conditions required for the plasma pretreatment and SiGe etching. For example, the process pressure required for the plasma pretreatment step for forming an Si—N etch passivation layer differs from that required for the SiGe etching step, which achieves an excellent SiGe selectivity. The process pressure required for the plasma pretreatment step preferably ranges from about 500 mTorr to 2000 mTorr. In contrast, the process pressure required for the SiGe etching step may be, for example, lower than or equal to 100 mTorr, and higher pressures can reduce an SiGe etch selectivity.

When reaction conditions are optimized for plasma pretreatment for the formation of the Si—N etch passivation layer, the SiGe etch selectivity is reduced, and an Si—N surface is poorly etched, but the Si surface exposed after SiGe etching suffers Si loss, which can lead to undesirable profiles such as necking or mushroom shapes. On the other hand, when reaction conditions are optimized for SiGe etching, the passivation effect on the Si layer can be reduced, resulting in a decrease in selectivity, and a nitride film may be formed partially on the SiGe region, significantly reducing etch uniformity between the stacks.

In addition, when the plasma pretreatment and SiGe etching for formation of the Si—N etch passivation film are performed the simultaneously, etching may be performed before the Si—N etch passivation film is sufficiently formed on the Si layers, thereby reducing the SiGe etch selectivity.

In contrast, when the plasma pretreatment for the formation of the Si—N etch passivation film is performed first, followed by SiGe etching, individual reaction conditions, such as pressure, time, and flow rate, of the plasma pretreatment and SiGe etching steps can be optimized. Accordingly, the nitride film may be selectively formed on the Si layer surface and the SiGe etching conditions can be optimized, thereby improving both the SiGe selectivity and the etch uniformity between the Si—SiGe stack.

FIG. 3B is a schematic flowchart illustrating a method of processing a substrate according to another embodiment of the present disclosure.

Referring to FIG. 3B, the illustrated method of processing a substrate includes the plasma pretreatment step S310, a substrate transfer step S315, and the SiGe etching step S320. A native oxide removing step may be added prior to the plasma pretreatment step S310.

Unlike the method illustrated in FIG. 3A, the method illustrated in FIG. 3B performs the plasma pretreatment step S310 and the SiGe etching step S320 as ex situ processes in different reaction chambers.

The method illustrated in FIG. 3A has an advantage in terms of throughput since both the plasma pretreatment step S310 and the SiGe etching step S320 are performed in a single chamber. However, in the method illustrated in FIG. 3A, a temperature of the susceptor within the reaction chamber needs to be changed for each step. For example, in the plasma pretreatment step for forming the Si—N etch passivation layer, reaction efficiency is better at high temperatures, and SiGe etching can have better etching efficiency at low temperatures. Accordingly, to improve the efficiency of each step, the temperature of the susceptor needs to be changed at each step.

In contrast, the method illustrated in FIG. 3B does not require changing temperatures of susceptors in a first chamber and a second chamber. For example, the plasma pretreatment step may be performed in the first chamber at a temperature of the susceptor (i.e., a substrate temperature) close to 40° C., the substrate may be transferred to the second chamber, and the SiGe etching step may be performed in the second chamber at a temperature of the susceptor close to −40° C.

For this ex situ process, the substrate transfer step S315 is included between these steps. A plasma pretreatment step S310 may be performed in a first reaction chamber, such as the example illustrated in FIG. 5A, and an etching step S320 may be performed in a second reaction chamber, such as the example illustrated in FIG. 5B. When the plasma pretreatment step S310 for the substrate in the first reaction chamber is completed, the substrate is transferred from the first reaction chamber to the second reaction chamber.

The substrate to be treated, that is, a substrate in which Si and SiGe layers are alternately stacked, is disposed on a susceptor within each reaction chamber. Subsequently, the substrate is heated as needed. Subsequently, stabilization within the reaction chamber may be performed using an inert gas such as argon.

Referring to FIGS. 3A and 3B, in the plasma pretreatment step S310, a nitrogen-containing pretreatment gas is converted into plasma to modify the surfaces of the Si layers in the Si—SiGe stack to silicon nitride.

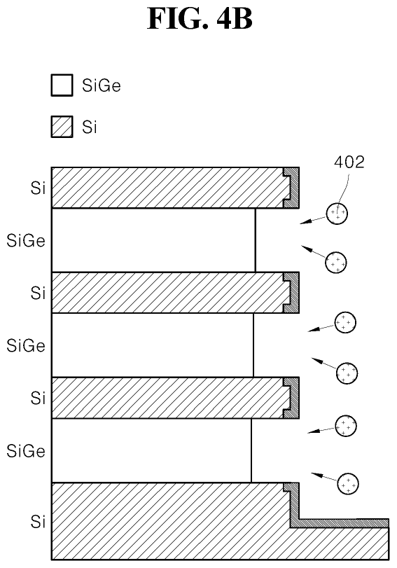

FIG. 4A schematically illustrates an example in which a silicon nitride film is formed on the surfaces of the Si layers during nitrogen-containing gas plasma pretreatment. As illustrated in FIG. 4, nitrogen radicals generated by a nitrogen-containing gas 401 react with Si on the surfaces of the Si layers to modify the surfaces of the Si layers to form silicon nitride thereon, such that silicon nitride is formed on the surfaces of the Si layers.

Since Si is more reactive to nitrogen radicals than SiGe, in this step, the Si on the surface of the Si layer reacts with nitrogen radicals, forming a silicon nitride film on the exposed surface of the Si layer rather than on the SiGe layer. As described above, the nitridation reaction of Ge requires a higher activation energy than the nitridation reaction of Si. Due to this difference in activation energy, a window within which a nitride film may be selectively formed on only the Si layer may be present, and using this window, an Si—N film may be formed primarily on Si.

The Si—N bond energy is about 355 KJ/mol, which is significantly higher than the Si—Si bond energy of about 222 KJ/mol. Accordingly, the generated silicon nitride film exhibits low reactivity toward SiGe etching gases, such as ClF₃, during the SiGe etching step, and in addition, since the etching selectivity of SiGe relative to SiN is significantly high, it may serve as an etch passivation film.

The gas available in the plasma pretreatment step S310 may include a nitrogen-containing gas. In particular, the gas available in the plasma pretreatment step S310 is preferably nitrogen gas or may include nitrogen gas.

The plasma pretreatment step S310 is preferably performed under a process pressure condition of about 0.5 to 2.0 Torr, and more preferably under a process pressure condition of about 0.5 to 1.0 Torr. When the process pressure exceeds about 2.0 Torr in the plasma pretreatment step S310, SiGe—N may be partially formed within the SiGe region, thereby reducing SiGe etch efficiency and etch uniformity. On the other hand, when the process pressure is less than about 0.5 Torr, Si—N cannot be sufficiently formed, resulting in insufficient selectivity improvement.

The plasma pretreatment step S310 is preferably performed under an RF power condition of about 100 to 1,500 W. When the RF power for plasma generation of the pretreatment gas exceeds about 1,500 W, SiGe—N may be partially formed within the SiGe region, thereby reducing SiGe etch efficiency and etch uniformity. The lower limit of the RF power is preferably about 100 W or higher to ensure smooth plasma discharge. For example, in a CCP type, plasma discharge may not occur when the RF power is less than about 100 W.

The plasma pretreatment step S310 is preferably performed under an RF power application time of about 5 to 60 seconds. Here, the RF power application time may refer to the plasma pretreatment time or the residence time of the pretreatment gas within the reaction chamber. When the plasma pretreatment time is less than 5 seconds, the Si layers cannot be uniformly modified, making it difficult to suppress Si layer loss during the SiGe etching step S320. Meanwhile, the plasma pretreatment time is preferably about 60 seconds or less, more preferably about 50 seconds or less. When the plasma pretreatment time exceeds about 60 seconds, SiGe—N may be partially formed within the SiGe region, which can reduce SiGe etching efficiency and etch uniformity.

In the plasma pretreatment step S310, a flow rate of the nitrogen-containing gas may range from about 10 to 300 sccm, but is not necessarily limited thereto.

In the plasma pretreatment step S310, the substrate temperature may range from about-40 to 40° C. At the substrate temperature of about 40° C. or less, Si is highly reactive to nitrogen radicals, while SiGe is less reactive to nitrogen radicals, thereby achieving a sufficient selective surface modification effect on the Si layer. Meanwhile, when the substrate temperature exceeds about 40° C., the reactivity of SiGe to nitrogen radicals can increase significantly, thereby reducing the selective surface modification effect on the Si layer. In addition, at the substrate temperature, which is lower than about −40° C., Si is also less reactive to nitrogen radicals, making it difficult to achieve the selective surface modification effect on the Si layer.

After the plasma pretreatment step S310, purge gas may be supplied into the reaction chamber to perform purge and pumping.

Subsequently, in the SiGe etching step S320, the SiGe layers are etched using an etching gas.

A reaction chamber internal stabilization step may be performed using an inert gas prior to the SiGe etching step S320.

FIG. 4B schematically illustrates an example in which SiGe layers are etched in a state in which the surfaces of the Si layers are modified into silicon nitride.

As in the example illustrated in FIG. 4B, an etching gas 402 with a high etch selectivity with respect to SiGe may be supplied into the reaction chamber to etch the SiGe layers. In this case, the silicon nitride film formed on the surfaces of the Si layers may serve as the etch passivation film, thereby reducing or suppressing loss of the Si layers. In addition, since an unwanted etch passivation film is not formed on the SiGe layer, a reduction in etch uniformity can be prevented.

In the SiGe etching step S320, the etching gas may contain a fluorine component. The etching gas may contain a fluorine gas. The etching gas may contain a nitrogen trifluoride gas (NF₃). More preferably, the etching gas may contain an inter-halogen gas containing a fluorine component, such as ClF₃, ClF₅, ClF, BrF, or BrF₅. When using the inter-halogen gas containing a fluorine component, the etch selectivity of SiGe with respect to SiN may be significantly higher, thereby reducing the loss of the Si layer.

When the etching gas component, such as an inter-halogen compound, is in a gaseous state, it may be supplied directly into the reaction chamber. On the other hand, when the inter-halogen compound is in a liquid state, it may be vaporized using a vaporizer and supplied into the reaction chamber. The interhalogen compound may be supplied alone into the reaction chamber, or may be supplied into the reaction chamber together with an inert gas such as argon gas or helium gas.

A flow rate of the etching gas may range from about 5 to 100 sccm.

Meanwhile, to improve etching efficiency, the etching gas may be converted into plasma, or the substrate may be heated.

After the SiGe etching step S320, purge gas may be supplied into the reaction chamber to perform purge and pumping.

Meanwhile, to enhance the protection effect of the Si layers, the plasma pretreatment step S310 and the SiGe etching step S320 may be repeated multiple times.

When the SiGe etching step is performed, the exposed surface of the Si layer also increases. Accordingly, by repeating the plasma pretreatment step S310 and the SiGe etching step S320, SiGe may be etched in a state in which the exposed surface of the Si layer is further modified, thereby further enhancing the protection effect of the Si layers.

Meanwhile, removing a native oxide layer of the Si—SiGe stack may be additionally included prior to the plasma pretreatment step.

In the native oxide removing step, the native oxide layer on the exposed side surfaces of the stack in which the Si and SiGe layers are alternately stacked is removed by a native oxide removal (NOR) process.

The native oxide layer is typically formed to a thickness of about 1.5 to 2.5 nm. Accordingly, in the native oxide layer removing step, a corresponding thickness of the native oxide layer is removed. Considering process margins, the native oxide removing step is preferably performed under process conditions in which oxide of at least 3 to 4 nm may be etched. The native oxide removing step may be performed in the same reaction chamber as the plasma pretreatment step S310, but is not limited thereto.

Meanwhile, in the native oxide removing process, a process temperature of less than about 100° C. is suitable. This is because high-temperature processes may cause Ge diffusion at the Si/SiGe interface during native oxide removal. This can reduce the etching resistance of the Si layer in the subsequent etching step.

The native oxide removal may be performed using a HF/NH₃ mixed gas or hydrogen gas. For example, when the native oxide removing step is performed by using the HF/NH₃ mixed gas, the exposed side surfaces of each Si and SiGe layer in the stack in which the Si and SiGe layers are alternately stacked may be modified with hydrogen (—H). By removing the native oxide, it is possible to not only facilitate the surface modification of the Si layer, but also improve the etching rate and uniformity of the SiGe layer. Meanwhile, to improve native oxide removal efficiency, the reactant gas may be converted into plasma, or the substrate may be heated.

FIG. 5A schematically illustrates an example of a first reaction chamber in which the nitrogen-containing gas plasma pretreatment step is performed. FIG. 5B schematically illustrates an example of a second reaction chamber in which an SiGe etching step is performed.

FIGS. 5A and 5B schematically illustrate examples of reaction chambers in which plasma pretreatment and etching steps are performed.

Referring to FIGS. 5A and 5B, the method of processing a substrate according to the present disclosure may perform plasma pretreatment and etching in a single reaction chamber 510. That is, in the method of processing a substrate according to the present disclosure, the plasma pretreatment step S310 and the etching step S320 may be performed in situ. In addition, when a native oxide film removing step is provided, the native oxide film removing step, the plasma pretreatment step S310, and the etching step S320 may be performed in situ.

In addition, as in the method illustrated in FIG. 3B, the plasma pretreatment step S310 may be performed in a first reaction chamber illustrated in FIG. 5A, and the SiGe etching step S320 may be performed in a separate second reaction chamber illustrated in FIG. 5B. That is, the plasma pretreatment step S310 and the SiGe etching step S320 may be performed ex situ.

A susceptor 520 for supporting a substrate 501 is disposed at a lower portion of the reaction chamber 510. A heater is disposed on the susceptor 520 to provide a required substrate temperature.

A gas supply line 530 for supplying a nitrogen-containing pretreatment gas 502 and a fluorine-containing etching gas 503 into the reaction chamber 510 is disposed at an upper end of the reaction chamber 510.

Only one gas supply line is illustrated in FIGS. 5A and 5B, but two or more gas supply lines may be disposed if necessary. For example, only the pretreatment gas 502 may be supplied into the reaction chamber 510 through a single gas supply line. In another example, the pretreatment gas 502 and the inert gas may be supplied into the reaction chamber 510 through a single gas supply line. In still another example, the pretreatment gas 502 and the inert gas may be supplied into the reaction chamber 510 through separate gas supply lines. The etching gas 503 may also be supplied into the reaction chamber 510 alone, together with the inert gas, or separately from the inert gas.

A gas distribution unit 540 connected to the gas supply line 530 is disposed at an upper portion of the reaction chamber 510. A showerhead 550 is disposed below the gas distribution unit 540. The gas distribution unit 540 and the showerhead 550 may be disposed as a single module within the reaction chamber 510. In another example, the gas distribution unit 540 and the showerhead 550 may be disposed separately within the reaction chamber 510. A plasma generation region 535 may be formed between the gas distribution unit 540 and the showerhead 550. To this end, for example, the gas distribution unit 540 may be connected to an RF power source, and the showerhead 550 may be grounded.

In the plasma pretreatment step S310, as described above, the nitrogen-containing pretreatment gas may be excited into plasma (remote plasma method) above the showerhead 550. As another example, the nitrogen-containing pretreatment gas may be excited into plasma (direct plasma method) between the showerhead 550 and the susceptor 520. To minimize the impact on the substrate, the nitrogen-containing pretreatment gas may preferably be excited into plasma above the showerhead 550. In the case of the direct plasma method, physical damage due to ion bombardment may occur. In contrast, the remote plasma method enables ion filtering, thereby minimizing the risk of such physical damage.

As described above, according to the method of processing a substrate according to the present disclosure, the surfaces of silicon layers may be modified into silicon nitride through plasma pretreatment with the nitrogen-containing gas prior to selective lateral etching of the SiGe layers in the Si—SiGe stack. Accordingly, by etching silicon germanium (SiGe) using silicon nitride as the etch passivation film, the etch selectivity of silicon germanium can be increased, and the formation of nitrogen-containing compounds on the surface of silicon germanium during etching can be suppressed, thereby suppressing a reduction in etch uniformity.

### EMBODIMENTS

Hereinafter, the configuration and operation of the present disclosure will be described in more detail through exemplary embodiments of the present disclosure. However, this is suggested as exemplary examples of the present disclosure and may not be construed as limiting the present disclosure thereby in any sense.

Since contents not described herein may be technically inferred by those skilled in the art, a description thereof will be omitted.

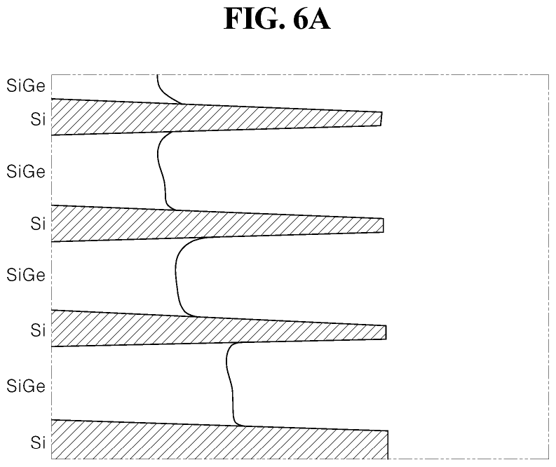

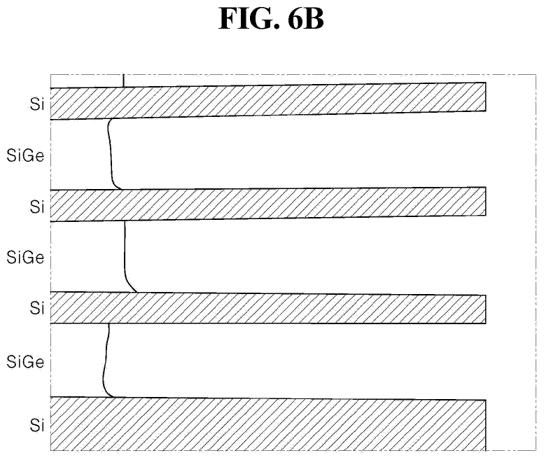

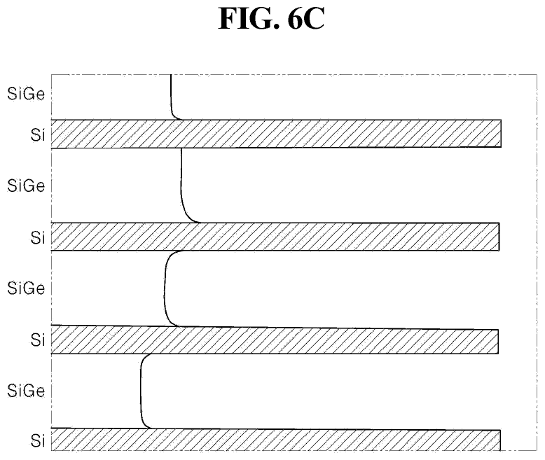

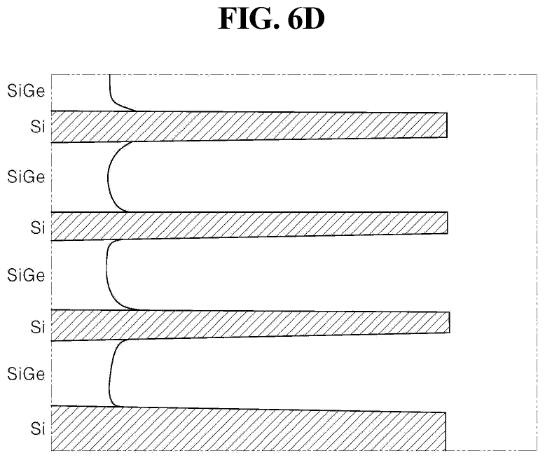

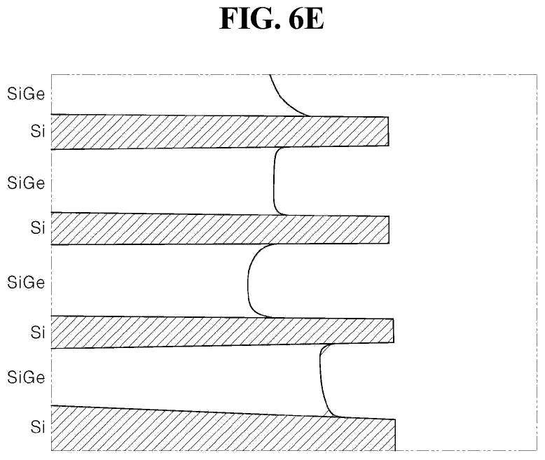

FIGS. 6A to 6E illustrate SiGe etching results according to the process pressure of the plasma pretreatment step.

FIG. 6A illustrates SiGe etched with ClF₃ gas without plasma pretreatment. FIG. 6B illustrates SiGe etched with ClF₃ gas after plasma pretreatment using N₂ gas at a 500 mTorr pressure. FIG. 6C illustrates SiGe etched with ClF₃ gas after plasma pretreatment using N₂ gas at a 1000 mTorr pressure. FIG. 6D illustrates SiGe etched with ClF₃ gas after plasma pretreatment using N₂ gas at a 2000 mTorr pressure. FIG. 6E illustrates SiGe etched with ClF₃ gas after plasma pretreatment using N₂ gas at a 2500 mTorr pressure.

In FIGS. 6B to 6E, the plasma pretreatment was performed under the following conditions: a substrate temperature of 20° C., RF power of 1000 W, and a plasma exposure time of 30 seconds, and both plasma pretreatment and SiGe etching were performed ex situ. In addition, in FIGS. 6A to 6E, a native oxide layer removing process was performed on the substrate using a HF/NH₃ mixed gas.

Referring to FIGS. 6A to 6E, the examples of FIGS. 6B to 6D in which SiGe etching was performed after nitrogen plasma pretreatment exhibited significantly less loss of the Si layer than that of FIG. 6A in which SiGe etching was performed without plasma pretreatment. Meanwhile, when the reaction chamber pressure during plasma pretreatment was 2,500 mTorr, SiGe—N was partially formed in the SiGe region, resulting in poor SiGe etching (see FIG. 6E).

In addition, when the reaction chamber pressure during plasma pretreatment was 500 and 1,000 mTorr, a higher SiGe etch selectivity was observed compared to when the reaction chamber pressure was 2,000 mTorr.

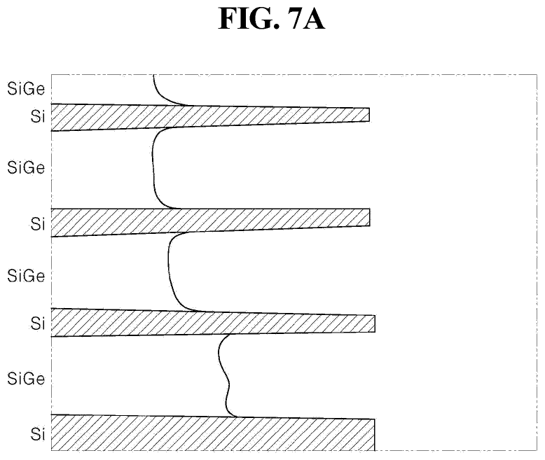

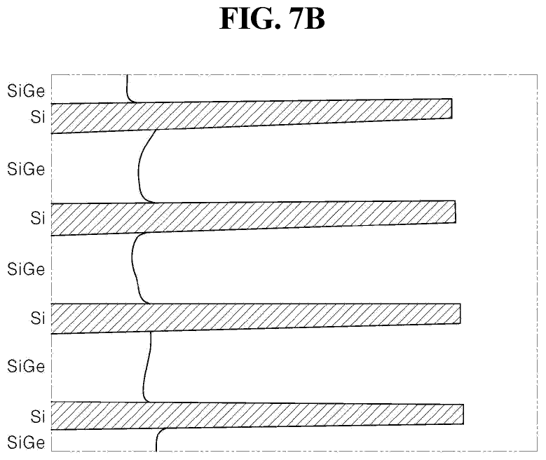

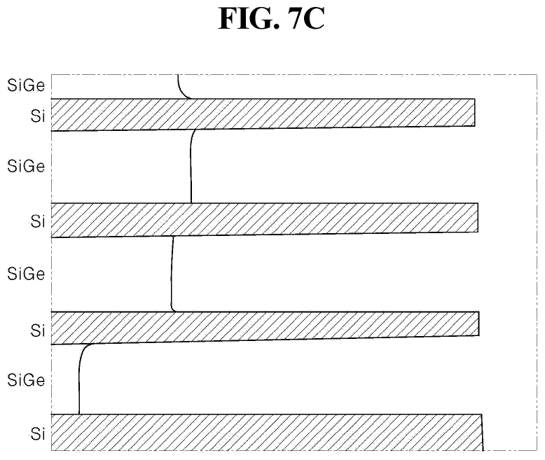

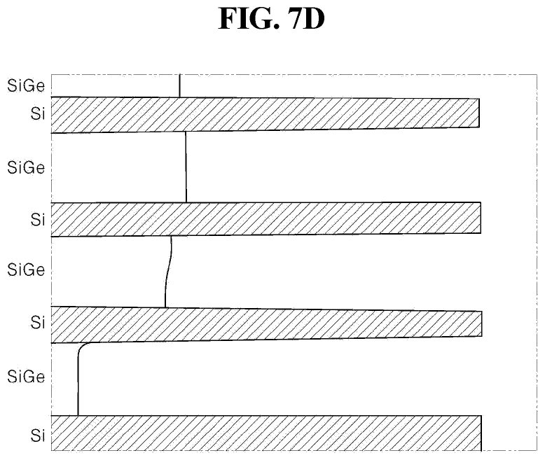

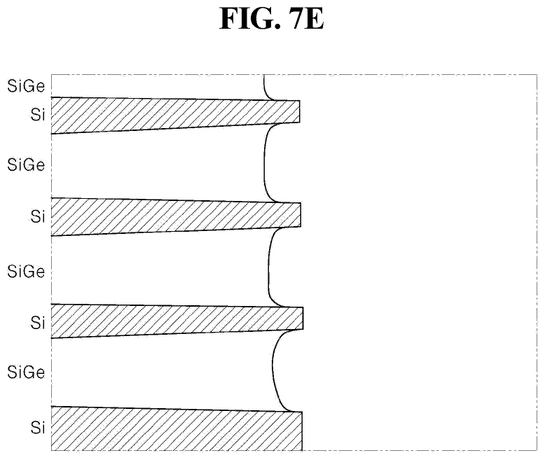

FIGS. 7A to 7E illustrate SiGe etching results according to the RF power of the plasma pretreatment step.

FIG. 7A illustrates SiGe etched with CF₃ gas without plasma pretreatment. FIG. 7B illustrates SiGe etched with ClF₃ gas after plasma pretreatment using N₂ gas under an RF power condition of 100 W. FIG. 7C illustrates SiGe etched with ClF₃ gas after plasma pretreatment using N₂ gas under an RF power condition of 1000 W. FIG. 7D illustrates SiGe etched with ClF₃ gas after plasma pretreatment using N₂ gas under an RF power condition of 1500 W. FIG. 7E illustrates SiGe etched with ClF₃ gas after plasma pretreatment using N₂ gas under an RF power condition of 2000 W.

In FIGS. 7B to 7E, the plasma pretreatment was performed under the following conditions: a substrate temperature of 20° C., an internal pressure of 1000 mTorr in the first reaction chamber, and a plasma exposure time of 30 seconds, and both plasma pretreatment and SiGe etching were performed ex situ. In addition, in FIGS. 7A to 7E, a native oxide layer removing process was previously performed on the substrate using a HF/NH₃ mixed gas.

Referring to FIGS. 7A to 7E, the examples of FIGS. 7B to 7D in which SiGe etching was performed after nitrogen plasma pretreatment exhibited significantly less loss of the Si layer than that of FIG. 7A in which SiGe etching was performed without plasma pretreatment. Meanwhile, when the RF power during plasma pretreatment was 2000 W, SiGe—N was partially formed in the SiGe region, resulting in poor SiGe etching (see FIG. 7E).

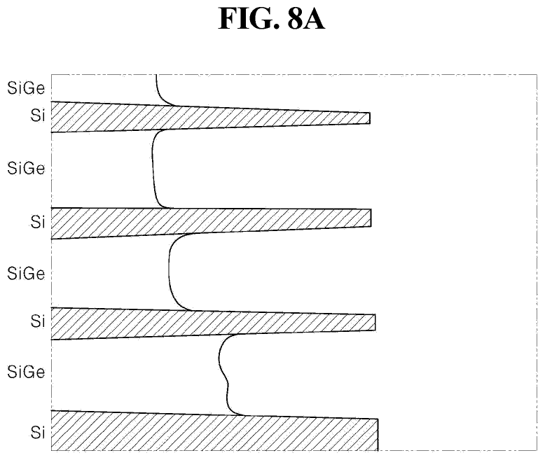

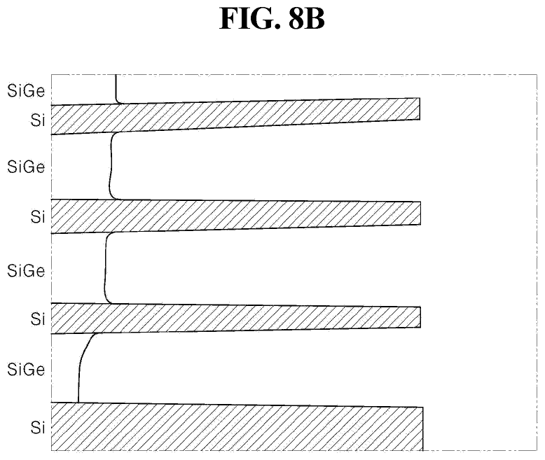

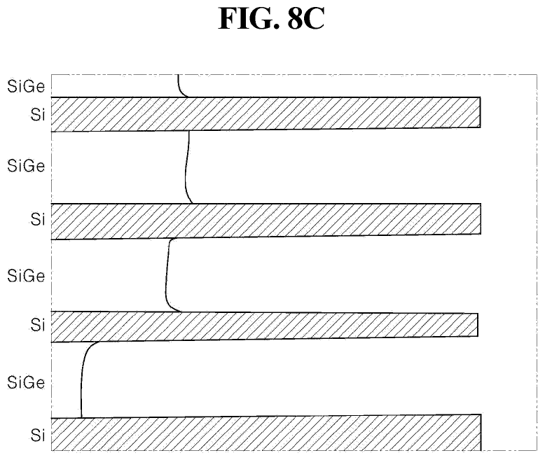

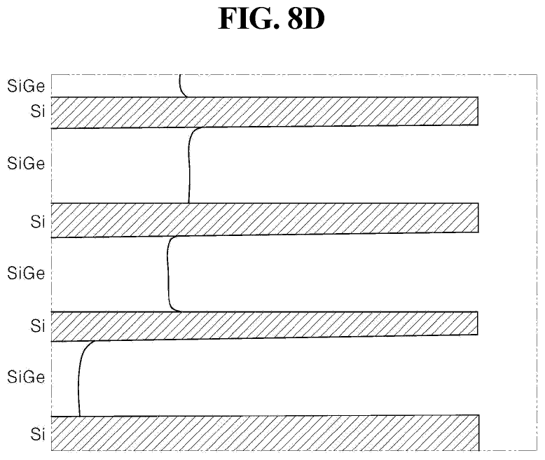

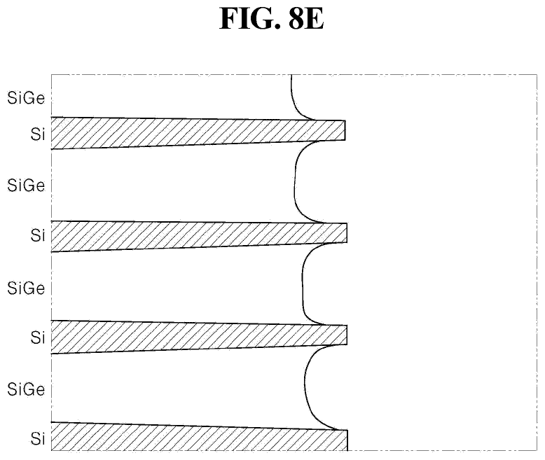

Table 1 and FIGS. 8A to 8E illustrate SiGe etching results according to plasma exposure time in the plasma pretreatment step.

FIG. 8A illustrates SiGe etched with ClF₃ gas without plasma pretreatment. FIG. 8B illustrates SiGe etched with ClF₃ gas after plasma pretreatment using N₂ gas under a plasma exposure condition of 5 seconds. FIG. 8C illustrates SiGe etched with ClF₃ gas after plasma pretreatment using N₂ gas under a plasma exposure time condition of 30 seconds. FIG. 8D illustrates SiGe etched with ClF₃ gas after plasma pretreatment using N₂ gas under a plasma exposure time condition of 60 seconds. FIG. 8E illustrates SiGe etched with ClF₃ gas after plasma pretreatment using N₂ gas under a plasma exposure time condition of 100 seconds.

TABLE 1

| Plasma | Average Si | Average SiGe | SiGe |
|---|---|---|---|
| Exposure | layer etch | layer etch | layer |
| time | amount | amount | etch |
| (seconds) | (Å) | (Å) | selectivity |
| 0 | 9.0 | 196.8 | 21.9 |
| 30 | 5.8 | 242.9 | 41.8 |
| 100 | 4.4 | 14.4 | 3.3 |

In Table 1 and FIGS. 8B to 8E, the plasma pretreatment was performed under the following conditions: a substrate temperature of 20° C., an internal pressure of 1000 mTorr in the first reaction chamber, and RF power of 1000 W, and both plasma pretreatment and SiGe etching were performed ex situ. In addition, in Table 1 and FIGS. 8A to 8E, a native oxide layer removing process was previously performed on the substrate using a HF/NH₃ mixed gas.

Referring to FIGS. 8A to 8E, the examples of FIGS. 8B to 8D in which SiGe etching was performed after nitrogen plasma pretreatment exhibited significantly less loss of the Si layer than that of FIG. 8A in which SiGe etching was performed without plasma pretreatment. Meanwhile, when the plasma exposure time during plasma pretreatment was 100 seconds, SiGe—N was partially formed in the SiGe region, resulting in poor SiGe etching (see FIG. 8E).

In addition, referring to Table 1, when nitrogen plasma pretreatment was performed for 30 seconds, both the etch selectivity and the SiGe layer etch amount exhibited significantly high values.

According to the method of processing a substrate of the present disclosure, prior to selective etching of the SiGe layers in the Si—SiGe stack, the surfaces of the silicon layers can be modified into silicon nitride through plasma pretreatment using a gas containing a nitrogen component, and this silicon nitride can serve as an etching passivation layer during the etching of silicon germanium (SiGe). Accordingly, in the SiGe etching step, the etch selectivity of SiGe can be increased during the etching of SiGe, and the formation of nitrogen-containing compounds on the surface of SiGe during etching can be suppressed, thereby suppressing a reduction in etch uniformity.

Furthermore, in the plasma pretreatment step applied to the present disclosure, the etching profile of SiGe can be controlled depending on factors such as process pressure, RF power, process time, etc.

Specific effects together with the above effects are described together with a description of the following detailed matters for carrying out the disclosure.

The above description focuses on various embodiments of the present disclosure, but various changes and modifications may be made within the scope of those skilled in the art. These changes and modifications may belong to the present disclosure unless they depart from the scope of the present disclosure. Accordingly, the scope of the present disclosure should be determined by the appended claims.

### DESCRIPTION OF REFERENCE NUMERALS

501: substrate
502: pretreatment gas
503: etching gas
510: reaction chamber
520: susceptor
530: gas supply line
535: plasma generation region
540: gas distribution unit
550: showerhead

1. A method of processing a substrate, which selectively etches SiGe layers laterally in a Si—SiGe stack in which Si layers and the SiGe layers are alternately stacked on the substrate, the method comprising:
(a) modifying surfaces of the Si layers to form silicon nitride thereon by generating plasma from a nitrogen-containing pretreatment gas; and
(b) etching the SiGe layers using an etching gas.

2. The method of claim 1, wherein, in the step (a), the pretreatment gas includes a nitrogen gas.

3. The method of claim 1, wherein, in the step (a), the plasma generation from the nitrogen-containing pretreatment gas is performed above a showerhead.

4. The method of claim 1, wherein the step (a) is performed under a process pressure condition of about 0.5 to about 2.0 Torr.

5. The method of claim 1, wherein the step (a) is performed under an RF power condition of about 100 to about 1,500 W.

6. The method of claim 1, wherein the step (a) is performed under an RF power application time condition of about 5 to about 60 seconds.

7. The method of claim 1, wherein, in the step (b), the etching gas includes a fluorine-containing component.

8. The method of claim 1, further comprising, prior to the step (a), removing a native oxide layer of the Si—SiGe stack.

9. The method of claim 1, wherein the steps (a) and (b) are repeated multiple times.

10. A method of processing a substrate, which selectively etches SiGe layers laterally in a Si—SiGe stack in which Si layers and the SiGe layers are alternately stacked on the substrate, the method comprising:
(a) arranging the substrate in a first reaction chamber and modifying surfaces of the Si layers to form silicon nitride thereon by generating plasma from a nitrogen-containing pretreatment gas;
(b) unloading the substrate from the first reaction chamber; and
(c) arranging the substrate in a second reaction chamber and etching the SiGe layers using an etching gas.

11. The method of claim 10, wherein, in the step (a), the pretreatment gas includes a nitrogen gas.

12. The method of claim 10, wherein, in the step (a), the plasma generation from the nitrogen-containing pretreatment gas is performed above a showerhead.

13. The method of claim 10, wherein the step (a) is performed under a process pressure condition of about 0.5 to about 2.0 Torr.

14. The method of claim 10, wherein the step (a) is performed under an RF power condition of about 100 to about 1,500 W.

15. The method of claim 10, wherein the step (a) is performed under an RF power application time condition of about 5 to about 60 seconds.

16. The method of claim 10, wherein, in the step (c), the etching gas includes a fluorine component.

17. The method of claim 10, further comprising, prior to the step (a), removing a native oxide film of the Si—SiGe stack.

18. The method of claim 10, wherein the steps (a) to (c) are repeated multiple times.
